(19) United States
(12) Patent Application Publication
(10) Pub. No.: US 2021/0108065 A1
(43) Pub. Date: Apr. 15, 2021

(54) POLYMERS AND PHOTORESIST COMPOSITIONS

(71) Applicant: ROHM AND HAAS ELECTRONIC MATERIALS LLC, Marlborough, MA (US)

(72) Inventors: Yang SONG, Farmingham, MA (US); Jong Keun PARK, Marlborough, MA (US); Emad AQAD, Northborough, MA (US); Mingqi LI, Shrewsbury, MA (US); Colin LIU, Marlborough, MA (US); James W. THACKERAY, Braintree, MA (US); Peter TREFONAS, III, Medway, MA (US)

(21) Appl. No.: 16/653,690

(22) Filed: Oct. 15, 2019

(51) Int. Cl. C08L 33/08; C08L 25/14; G03F 7/038; G03F 7/20

(52) U.S. Cl. CPC C08L 33/08; G03F 7/20; G03F 7/038; C08L 25/14

(57) ABSTRACT

A polymer comprising: a first repeating unit comprising a tertiary ester acid labile group; and a second repeating unit of Formula (1):

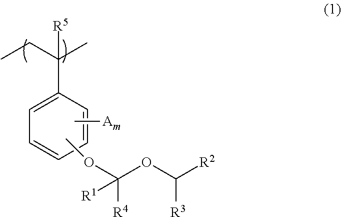

wherein R¹ to R⁵ are as provided herein; R² and R³ together do not form a ring; each A is independently a halogen, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted; and m is an integer of 0 to 4.

### FIELD

The present invention relates to photoresist compositions useful for photolithography and to polymers having use in such compositions. Specifically, the invention relates to chemically amplified photoresist compositions that are useful in forming thick photoresist layers and to polymers having use in such compositions.

### BACKGROUND

The Integrated Circuit (IC) industry has achieved the low cost of a bit by going towards smaller geometries. However, further miniaturization of the critical dimensions could not be realized by current lithographic techniques with similarly low production cost. NAND flash manufacturers have been looking into techniques for stacking multiple layers of memory cells to achieve greater storage capacity while still maintaining lower manufacturing cost per bit. Miniaturization of critical features while keeping the manufacturing cost low, has led to the development of stacked 3D structures for NAND applications. Such 3D NAND devices are denser, faster, and less expensive than the traditional 2D planar NAND devices.

The 3D NAND architecture comprises vertical channel and vertical gate architectures, and the stepped structure (known as “staircase”) is used to form an electrical connection between memory cells and bit lines or word lines. In constructing 3D NAND flash memories, manufacturers increase the number of stairs using a thick resist that allows for multiple trimming and etching cycles used for staircase formation. Maintaining good feature profile on each step is challenging since subsequent trimming-etching variations on critical dimension (CD) will be accumulated step by step and across the wafer.

The process of “staircase” formation that calls for the use of a single mask exposure of a thick KrF photo-resist to form several sets of stairs is considered as a relatively cost-effective approach. The application requires a photoresist thickness of 5 to 30 micrometers, for example, 8 to 30 micrometers or 8 to 25 micrometers. However, conventional KrF photoresists described in the literature are only designed for applications that require a much lower nanometer scale resist film thickness.

The use of thick film in KrF lithography for printing micrometer scale features is associated with unique technical challenges. Patterning a thick resist film requires sufficient film transparency at exposure wavelength to allow incident radiation to reach the bottom of the film. Moreover, thick resist film used in 3D NAND applications are subject to multiple resist thickness trim and dry etch cycles. Exposing thick resist film to trim and etch treatments can affect film structure uniformity and can lead to the formation of rough film surfaces and the formation of undesired voids in the film. Suitable thick resist films should be able to maintain film physical structure after each film thickness trim and etch treatment.

Therefore, there is a continuing need for chemical compositions that could be suitable for thick photoresists, which have good transparency at exposure wavelength, excellent retention of properties after thickness trimming and etching, and improved dissolution rates in aqueous alkaline developer after exposure and bake processes.

### SUMMARY

Provided is a polymer comprising: a first repeating unit comprising a tertiary ester acid labile group; and a second repeating unit of Formula (1):

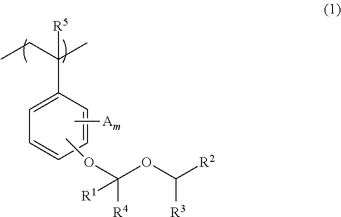

wherein R¹ is hydrogen, a substituted or unsubstituted C₁₋₁₂ alkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ haloalkyl; R² and R³ are each independently a straight chain or branched C₁₋₂₀ alkyl, a straight chain or branched C₁₋₂₀ haloalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, a C₇₋₂₀ aryloxyalkyl, or a monocyclic or polycyclic C₄₋₂₀ heteroaryl, each of which is substituted or unsubstituted, provided that R² and R³ together do not form a ring; R⁴ is a substituted or unsubstituted C₁₋₁₂ alkyl, a substituted or unsubstituted C₇₋₁₈ arylalkyl, a substituted or unsubstituted C₄₋₁₈ heteroarylalkyl, or a substituted or unsubstituted C₁₋₁₂ haloalkyl; R⁵ is hydrogen, fluorine, a substituted or unsubstituted C₁₋₅ alkyl, or a substituted or unsubstituted C₁₋₅ fluoroalkyl; each A is independently a halogen, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted; and m is an integer of 0 to 4.

Also provided is a photoresist composition, comprising: the polymer, a photoacid generator; and a solvent.

Also provided is a method of forming a pattern, the method comprising: applying a layer of the photoresist composition on a substrate; drying the applied photoresist composition to form a photoresist composition layer; exposing the photoresist composition layer to activating radiation; heating the exposed photoresist composition layer; and developing the exposed composition layer to form a resist pattern.

### BRIEF DESCRIPTION OF THE DRAWINGS

The above and other aspects of the present invention will become more apparent by describing in detail exemplary embodiments thereof with reference to the attached drawings, in which:

FIGS. 1A to 1K are representative diagrams schematically showing steps of a method of forming a staircase pattern in accordance with an embodiment of the present invention.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art of the disclosed subject matter. It will be further understood that terms, such as those defined in commonly used dictionaries, should be interpreted as having a meaning that is consistent with their meaning in the context of the relevant art and the present invention, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O—”; “carboxylic acid group” refers to a group having the formula “—C(═O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenylene group” refers to an alkenyl group having a valence of two; “cycloalkenyl group” refers to a non-aromatic cyclic divalent hydrocarbon group having at least three carbon atoms, with at least one carbon-carbon double bond; “aryl group” refers to a monovalent aromatic monocyclic or polycyclic ring system, and may include a group with an aromatic ring fused to at least one cycloalkyl or heterocycloalkyl ring; “arylene group” refers to an aryl group having a valence of two; “alkylaryl group” refers to an aryl group that has been substituted with an alkyl group; “arylalkyl group” refers to an alkyl group that has been substituted with an aryl group; “heterocycloalkyl group” refers to a cycloalkyl group having 1-3 heteroatoms as ring members instead of carbon; “heterocycloalkylene group” refers to a heterocycloalkyl group having a valence of two; “heteroaryl group” refers to an aromatic group having 1-4 heteroatoms as ring members instead of carbon; “aryloxy group” refers to “aryl-O—”; and “arylthio group” refers to “aryl-S—”. The prefix “hetero” means that the compound or group includes at least one member that is a heteroatom (e.g., 1, 2, or 3 heteroatom(s)) instead of a carbon atom, wherein the heteroatom(s) is each independently N, O, S, Si, or P. The prefix “halo” means a group including one more of a fluoro, chloro, bromo, or iodo substituent instead of a hydrogen atom. A combination of halo groups (e.g., bromo and fluoro), or only fluoro groups may be present. The term “(meth)acrylate” is inclusive of both methacrylate and acrylate, the term “(meth)allyl” is inclusive of both methallyl and allyl, and the term “(meth)acrylamide” is inclusive of both methacrylamide and acrylamide.

Unless otherwise specified, “substituted” means that at least one hydrogen atom on the group is replaced with another group, provided that the designated atom's normal valence is not exceeded. When the substituent is oxo (i.e., ═O), then two hydrogens on the atom are replaced. Combinations of substituents or variables are permissible. Exemplary groups that may be present on a “substituted” position include, but are not limited to, nitro (—NO₂), cyano (—CN), hydroxy (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof, C₂₋₆ alkyl ester (—C(═O)O-alkyl or —OC(═O)-alkyl), C₇₋₁₃ aryl ester (—C(═O)O-aryl or —OC(═O)-aryl), amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group. When a group is substituted, each atom in the group can be independently substituted or unsubstituted, provided that at least one atom is substituted. For example, a substituted C₃ alkyl group can be a group of the formula —CH₂C(═O)CH₃ or a group of the formula —CH₂C(═O)CH₍₃₋ₙ₎Yₙ, where each Y is independently a substituted or unsubstituted C₃₋₁₀ heterocycloalkyl and n is 1 or 2.

As noted above, there is a need for resist compositions having good transparency at exposure wavelength, excellent retention of mechano-physical properties after multiple thickness trimming and etch treatments, improved solubility in aqueous alkaline developer after exposure and bake, and suitable adhesion to substrates when coated as a thick film.

Disclosed herein is a resist polymer for a photoresist composition designed from thick film patterning. The resist polymer includes repeat units having a secondary vinyl ether protected hydroxystyrene, which when used in photoresist compositions can provide improved photospeed and lithographic performance.

In an embodiment, the polymer includes a first repeating unit comprising a tertiary ester acid labile group and a second repeating unit of Formula (1):

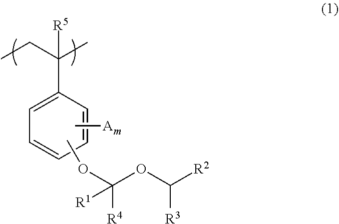

In Formula (1), R¹ is hydrogen, a substituted or unsubstituted C₁₋₁₂ alkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ haloalkyl. Preferably, R¹ is hydrogen, a substituted or unsubstituted C₁₋₆ alkyl, a substituted or unsubstituted C₆₋₁₂ aryl, a substituted or unsubstituted C₇₋₁₃ arylalkyl, or a substituted or unsubstituted C₁₋₆ haloalkyl.

In Formula (1), R² and R³ are each independently a straight chain or branched C₁₋₂₀ alkyl, a straight chain or branched C₁₋₂₀ haloalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, a C₇₋₂₀ aryloxyalkyl, or a monocyclic or polycyclic C₄₋₂₀ heteroaryl, each of which is substituted or unsubstituted, provided that R² and R³ together do not form a ring. Preferably R² and R³ are each independently a straight chain or branched C₁₋₆ alkyl, a straight chain or branched C₁₋₆ haloalkyl, a monocyclic or polycyclic C₃₋₁₀ cycloalkyl, a monocyclic or polycyclic C₆₋₁₂ aryl, or a C₇₋₁₃ aryloxyalkyl, each of which is substituted or unsubstituted, provided that R² and R³ together do not form a ring.

In Formula (1), R⁴ is a substituted or unsubstituted C₁₋₁₂ alkyl, a substituted or unsubstituted C₇₋₁₈ arylalkyl, a substituted or unsubstituted C₄₋₁₈ heteroarylalkyl, or a substituted or unsubstituted C₁₋₁₂ haloalkyl. Preferably, R⁴ is a substituted or unsubstituted methyl group.

In Formula (1), each A is independently a halogen, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted. Preferably each A is independently a halogen, a straight chain or branched C₁₋₆ alkyl, a monocyclic or polycyclic C₃₋₁₀ cycloalkyl, a monocyclic or polycyclic C₃₋₁₀ fluorocycloalkenyl, or a monocyclic or polycyclic C₆₋₁₂ aryl, each of which is substituted or unsubstituted. In Formula (1), m is an integer of 0 to 4, preferably 0 to 2, more preferably 0 or 1, even more preferably 0.

In Formula (1), R⁵ is hydrogen, fluorine, a substituted or unsubstituted C₁₋₅ alkyl, or a substituted or unsubstituted C₁₋₅ fluoroalkyl. Preferably, R⁵ is hydrogen or methyl.

In Formula (1), the vinyl ether protected hydroxy group may be connected in the ortho, meta, or para position of the phenyl ring. When m is 2 or more, groups A may be the same or different, and may be optionally connected to form a ring.

In an embodiment, the second repeating unit may be of Formula (1a):

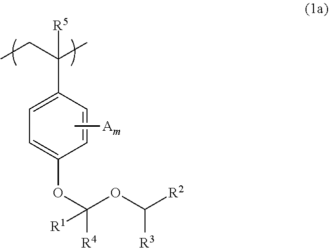

wherein R¹ to R⁵, A, and m are the same as described for Formula (1).

In a particular embodiment, the second repeating unit may be Formula (1b):

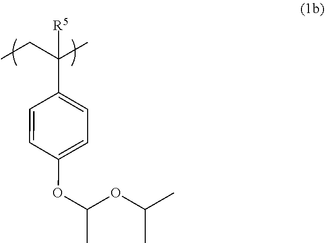

wherein R⁵ is the same as described for Formula (1).

The second repeating unit in the polymer may be obtained directly by polymerizing a corresponding monomer compound or by the method shown in Scheme 1. For example, the second repeating unit may be prepared by reacting a hydroxystyrene repeating unit of a polymer with a secondary vinyl ether in the presence of an acid catalyst. This reaction is shown in Scheme 1.

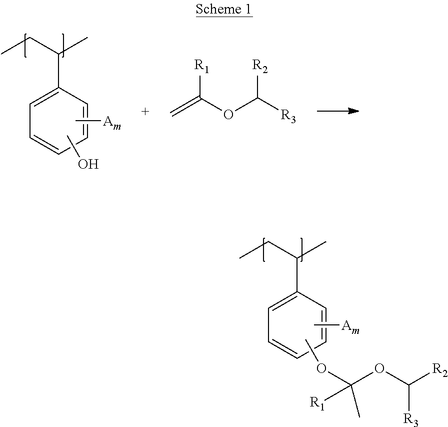

In Scheme 1, R¹ to R³, A, and m are the same as described for Formula (1). The repeating unit in the embodiment shown in Scheme 1 therefore corresponds to the second repeating unit of Formula (1) wherein R⁴ is methyl and R⁵ is hydrogen. It is to be understood that “the polymer including the second repeating unit of Formula (1)” refers to a second repeating unit of the polymer and is the same structure whether obtained directly from polymerizing a corresponding monomer compound or by the exemplary method shown in Scheme 1.

Non-limiting examples of secondary vinyl ethers may include the following compounds:

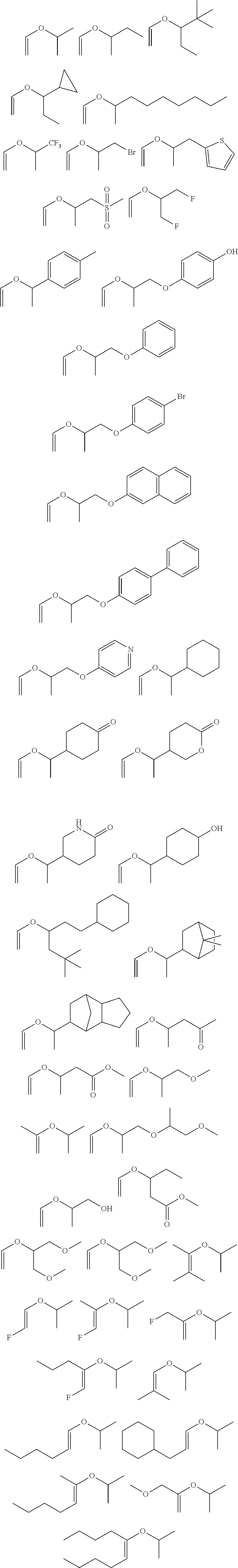

In addition to the second repeating unit, the polymer also includes a first repeating unit comprising a tertiary ester acid labile group. In an embodiment, the first repeating unit comprising the tertiary ester acid labile group may be derived from a monomer of Formula (2a) or Formula (2b):

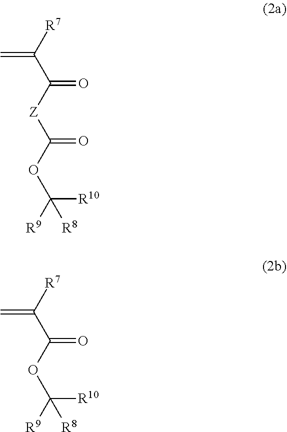

In Formulae (2a) and (2b), R⁷ is hydrogen, fluorine, a substituted or unsubstituted C₁₋₅ alkyl, or a substituted or unsubstituted C₁₋₅ fluoroalkyl. Preferably, R⁷ is hydrogen or methyl. In Formula (2a), Z is a linking unit comprising at least one carbon atom and at least one heteroatom. In an embodiment, Z can include 1 to 10 carbon atoms. In another embodiment, Z can be —OCH₂CH₂O—.

In Formulae (2a) and (2b), R⁸, R⁹, and R¹⁰ are each independently a straight chain or branched C₁₋₂₀ alkyl, a monocyclic or polycyclic C₃₋₂₀ cycloalkyl, a monocyclic or polycyclic C₃₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₄-20 heteroaryl, each of which is substituted or unsubstituted, and any two of R⁸, R⁹, and R¹⁰ together optionally form a ring. Preferably, R⁸, R⁹, and R¹⁰ are each independently a straight chain or branched C₁₋₆ alkyl, or a monocyclic or polycyclic C₃₋₁₀ cycloalkyl, each of which is substituted or unsubstituted, and any two of R⁸, R⁹, and R¹⁰ together optionally form a ring. For example, R⁸ can be a substituted C₃ alkyl group of the formula —CH₂C(═O)CH₍₃₋ₙ₎Yₙ, where each Y is independently a substituted or unsubstituted C₃₋₁₀ heterocycloalkyl and n is 1 or 2.

Non-limiting examples of monomers of Formula (2a) include:

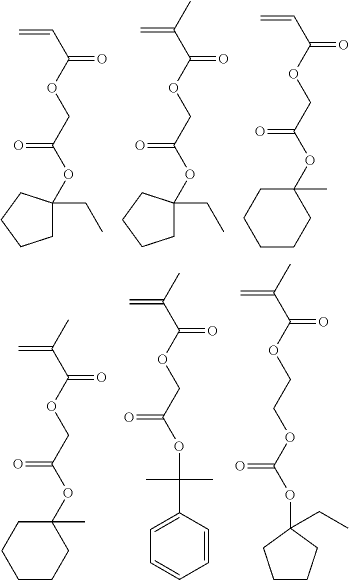

Non-limiting examples of monomers of Formula (2b) include:

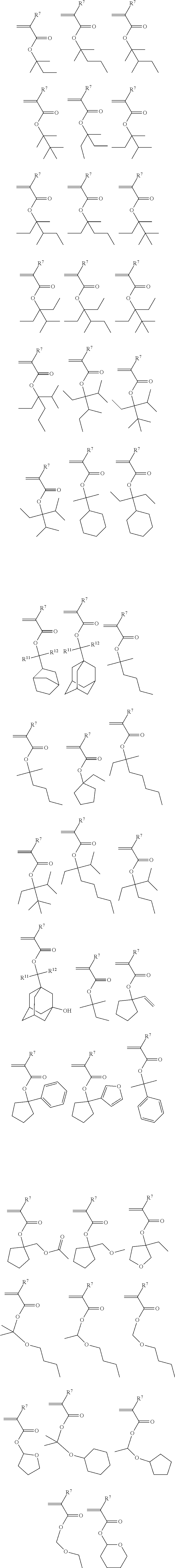

wherein R⁷ is as defined above.

Other exemplary monomers of Formulae (2a) or (2b) include the following:

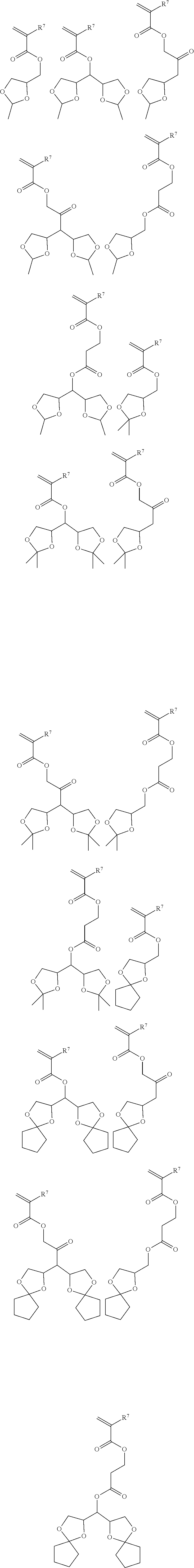

wherein R⁷ is as defined above.

The polymer may further include a third repeat unit derived from a monomer of formula (3):

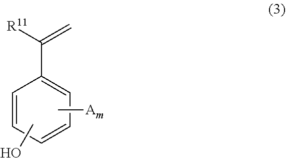

wherein R¹¹ is hydrogen, fluorine, a substituted or unsubstituted C₁₋₅ alkyl, or a substituted or unsubstituted C₁₋₅ fluoroalkyl, preferably hydrogen or methyl; and A and m are the same as A and m in the second repeating unit derived from the monomer of Formula (1). In other words, A and m are the same in the second repeating unit and the third repeating unit of the polymer.

In an embodiment, the polymer may include 1 to 30 mole percent (mol %), preferably 5 to 25 mol %, more preferably 5 to 20 mol % of the first repeating unit; and 70 to 99 mol %, preferably 75 to 95 mol %, more preferably 80 to 95 mol % of the second repeating unit, each based on the total number of moles of repeat units in the polymer.

In an embodiment, the polymer includes the first repeating unit, the second repeating unit, and the third repeating unit, wherein the polymer may include 1 to 30 mol %, preferably 5 to 25 mol %, more preferably 5 to 20 mol % of the first repeating unit; 1 to 60 mol %, preferably 10 to 50 mol %, more preferably 20 to 40 mol % of the second repeating unit; and 30 to 90 mol %, preferably 40 to 80 mol %, more preferably 50 to 80 mol % of the third repeating unit, each based on the total number of moles of repeat units in the polymer.

The polymer may have a weight average molecular weight (M_{w}) from 7,000 grams per mole (g/mol) to 50,000 g/mol, for example, preferably from 10,000 to about 30,000 g/mol, more preferably from 12,000 to about 30,000 g/mol, with a polydispersity index (PDI) of 1.3 to 3, preferably 1.3 to 2, more preferably 1.4 to 2. Molecular weight is determined by gel permeation chromatography (GPC) using polystyrene standards.

The polymers may be prepared using any suitable methods in the art. For example, one or more monomers corresponding to the repeating units described herein may be combined subsequently polymerized. For example, the polymer may be obtained by polymerization of the respective monomers under any suitable conditions, such as by heating at an effective temperature, irradiation with actinic radiation at an effective wavelength, or a combination thereof. In an embodiment, the second repeating unit in the polymer may be obtained by the method shown in Scheme 1.

Also provided is a photoresist composition including the polymer, a photoacid generator, and a solvent.

In the photoresist compositions of the invention, the polymer is typically present in the photoresist composition in an amount of from 10 to 99.9 wt %, preferably from 25 to 99 wt %, more preferably 50 to 95 wt %, based on the weight of the total solids. It will be understood that total solids includes the polymer and other non-solvent components including, but not limited to, PAGs, photo-destroyable bases, quenchers, surfactants, additional polymers, and other additives.

The photoresist compositions may include one or more polymers in addition to the polymer described above. Such additional polymers are well known in the photoresist art and include, for example, polyacrylates, polyvinylethers, polyesters, polynorbornenes, polyacetals, polyethylene glycols, polyamides, polyacrylamides, polyphenols, novolacs, styrenic polymers, polyvinyl alcohols.

The photoresist composition includes one or more photoacid generators (PAG)s. Photoacid generators generally include those photoacid generators suitable for the purpose of preparing photoresists. Photoacid generators include, for example, non-ionic oximes and various onium cation salts. Onium cations can be substituted or unsubstituted and include, for example, ammonium, phosphonium, arsonium, stibonium, bismuthonium, oxonium, sulfonium, selenonium, telluronium, fluoronium, chloronium, bromonium, iodonium, aminodiazonium, hydrocyanonium, diazenium (RN═N⁺R₂), iminium (R₂C═N⁺R₂), quaternary ammonium having two double-bonded substituents (R═N⁺═R), nitronium (NO₂⁺), bis(trarylphosphine)iminium ((Ar₃P)₂N⁺), tertiary ammonium having one triple-bonded substituent (R≡NH⁺), nitrilium (RC≡NR⁺), diazonium (N≡N⁺R), tertiary ammonium having two partially double-bonded substituents (R [symbol] N⁺H [symbol] R), pyridinium, quaternary ammonium having one triple-bonded substituent and one single-bonded substituent (R≡N⁺R), tertiary oxonium having one triple-bonded substituent (R≡O⁺), nitrosonium (N≡O⁺), tertiary oxonium having two partially double-bonded substituents (R [symbol] O⁺ [symbol] R), pyrylium (C₅H₅O⁺), tertiary sulfonium having one triple-bonded substituent (R≡S⁺), tertiary sulfonium having two partially double-bonded substituents (R [symbol] S⁺ [symbol] R), and thionitrosonium (N≡S⁺). In an embodiment, the onium ion is selected from a substituted or unsubstituted diaryiodonium, or a substituted and substituted triarylsulfonium. Examples of suitable onium salts can be found in U.S. Pat. Nos. 4,442,197, 4,603,101, and 4,624,912.

Suitable photoacid generators are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Another embodiment further provides a photoresist composition comprising a photoacid generator having formula G⁺A⁻, wherein A⁻ is an organic anion and G⁺ has formula (A):

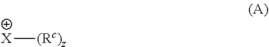

In formula (A), X may be S or I, each R^{c} may be halogenated or non-halogenated, and is independently a C₁₋₃₀ alkyl group; a polycyclic or monocyclic C₃₋₃₀ cycloalkyl group; a polycyclic or monocyclic C₄₋₃₀ aryl group, wherein when X is S, one of the R^{c} groups is optionally attached to one adjacent R^{c} group by a single bond, and z is 2 or 3, and wherein when X is I, z is 2, or when X is S, z is 3.

For example, cation G⁺ may be of formula (B), (C), or (D):

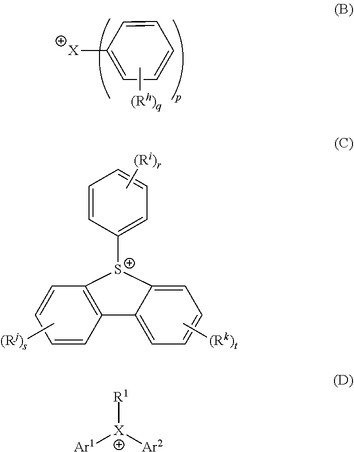

wherein X is I or S; R^{h}, Rⁱ, R^{j}, and R^{k} are unsubstituted or substituted and are each independently hydroxy, nitrile, halogen, C₁₋₃₀ alkyl, C₁₋₃₀ fluoroalkyl, C₃₋₃₀ cycloalkyl, C₁₋₃₀ fluorocycloalkyl, C₁₋₃₀ alkoxy, C₃₋₃₀ alkoxycarbonylalkyl, C₃₋₃₀ alkoxycarbonylalkoxy, C₃₋₃₀ cycloalkoxy, C₅₋₃₀ cycloalkoxycarbonylalkyl, C₅₋₃₀ cycloalkoxycarbonylalkoxy, C₁₋₃₀ fluoroalkoxy, C₃₋₃₀ fluoroalkoxycarbonylalkyl, C₃₋₃₀ fluoroalkoxycarbonylalkoxy, C₃₋₃₀ fluorocycloalkoxy, C₅₋₃₀ fluorocycloalkoxycarbonylalkyl, C₅₋₃₀ fluorocycloalkoxycarbonylalkoxy, C₆₋₃₀ aryl, C₆₋₃₀ fluoroaryl, C₆₋₃₀ aryloxy, or C₆₋₃₀ fluoroaryloxy, each of which is unsubstituted or substituted; Ar¹ and Ar² are independently C₁₀₋₃₀ fused or singly bonded polycyclic aryl groups; R¹ is a lone pair of electrons where X is I, or a C₆₋₂₀ aryl group where X is S; p is an integer of 2 or 3, wherein when X is I, p is 2, and where X is S, p is 3, q and r are each independently an integer from 0 to 5, and

In an embodiment, the PAG is a sulfonium salt represented by Formula (6):

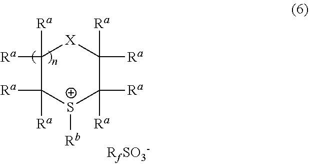

In Formula (6), R^{b} may be a substituted or unsubstituted C₂₋₂₀ alkenyl, a substituted or unsubstituted C₃₋₂₀ cycloalkyl, a substituted or unsubstituted C₅₋₃₀ aryl, or a substituted or unsubstituted C₄₋₃₀ heteroaryl. In another embodiment, R^{b} may be a substituted or unsubstituted C₅₋₃₀ aryl or a substituted or unsubstituted C₄₋₃₀ heteroaryl. For example, R may be a substituted phenyl group. In an embodiment, R^{b} may be a phenyl group substituted with one or more C₁₋₃₀ alkyl or C₃₋₈ cycloalkyl, for example, C₁₋₅ alkyl or C₃₋₆ cycloalkyl.

In an embodiment, R^{b} may optionally include an acid-sensitive functional group capable of being hydrolyzed at pH<7.0, for example, a tertiary ester, a tertiary ether, or a tertiary carbonate group.

In Formula (6), R^{a} at each occurrence can be the same or different, and may each independently be hydrogen, a halogen, a straight chain or branched C₁₋₂₀ alkyl, a straight chain or branched C₁₋₂₀ fluoroalkyl, a straight chain or branched C₂₋₂₀ alkenyl, a straight chain or branched C₂₋₂₀ fluoroalkenyl, a monocyclic or polycyclic C₃₋₂₀ cycloalkyl, a monocyclic or polycyclic C₃₋₂₀ fluorocycloalkyl, a monocyclic or polycyclic C₃₋₂₀ cycloalkenyl, a monocyclic or polycyclic C₃₋₂₀ fluorocycloalkenyl, a monocyclic or polycyclic C₃₋₂₀ heterocycloalkyl; a monocyclic or polycyclic C₃₋₂₀ heterocycloalkenyl; a monocyclic or polycyclic C₆₋₂₀ aryl, a monocyclic or polycyclic C₆₋₂₀ fluoroaryl, a monocyclic or polycyclic C₄₋₂₀ heteroaryl, or a monocyclic or polycyclic C₄₋₂₀ fluoroheteroaryl, each of which except hydrogen may be substituted or unsubstituted. In an embodiment, each R^{a} may be hydrogen.

Any two of R^{a} groups may be optionally connected via Z′ to form a ring, wherein Z′ may be a single bond or at least one linker selected from —C(═O)—, —S(═O)—, —S(═O)₂—, —C(═O)O—, —C(═O)NR′—, —C(═O)—C(═O)—, —O—, —CH(OH)—, —CH₂—, —S—, and —BR′—, wherein R′ may be hydrogen or a C₁₋₂₀ alkyl group.

Each R^{a} may be optionally substituted, independently from other R^{a} groups, with at least one selected from —OY, —NO₂, —CF₃, —C(═O)—C(═O)—Y, —CH₂OY, —CH₂Y, —SY, —B(Y), —C(═O)NRY, —NRC(═O)Y, —(C═O)OY, and —O(C═O)Y, wherein Y is a straight chain or branched C₁₋₂₀ alkyl, a straight chain or branched C₁₋₂₀ fluoroalkyl, a straight chain or branched C₂₋₂₀ alkenyl, a straight chain or branched C₂₋₂₀ fluoroalkenyl, a straight chain or branched C₂₋₂₀ alkynyl, a straight chain or branched C₂₋₂₀ fluoroalkynyl, a C₆₋₂₀ aryl, a C₆₋₂₀ fluoroaryl, or an acid-sensitive functional group capable of being hydrolyzed at pH<7.0, such as a tertiary ester, tertiary ether, or tertiary carbonate group.

In Formula (6), X may be a divalent linking group such as O, S, Se, Te, NR″, S═O, S(═O)₂, C═O, (C═O)O, O(C═O), (C═O)NR″, or NR″(C═O), wherein R″ may be hydrogen or a C₁₋₂₀ alkyl. n may be an integer of 0, 1, 2, 3, 4, and 5. In an embodiment, X may be 0.

In Formula (6), R_{f}SO₃⁻ is a fluorinated sulfonate anion, wherein R_{f} is a fluorinated group. In an embodiment, R_{f} may be —C(R¹²)_{y}(R¹³)_{z}, wherein R¹² may be independently selected from F and fluorinated methyl, R¹³ may be independently selected from hydrogen, C₁₋₅ linear or branched or cycloalkyl and C₁₋₅ linear or branched or cyclic fluorinated alkyl, y and z may be independently an integer from 0 to 3, provided that the sum of y and z is 3 and at least one of R¹² and R¹³ contains fluorine, wherein the total number of carbon atoms in R_{f} may be from 1 to 6. In the formula —C(R¹²)_{y}(R¹³)z, both R¹² and R¹³ are attached to C₁₋₅ Preferably, there is at least one fluorine atom or fluorinated group bonded to the carbon atom at the alpha position with respect to the SO₃⁻ group. In an embodiment, y may be 2, and z may be 1. In these embodiments, each R¹² may be F, or one R¹² may be F and the other R¹² may be fluorinated methyl. A fluorinated methyl may be monofluoromethyl (—CH₂F), difluoromethyl (—CHF₂), and trifluoromethyl (—CF₃). In another embodiment, R¹³ may be independently selected from C₁₋₅ linear or branched fluorinated alkyl. A fluorinated alkyl may be perfluorinated alkyl.

The one or more PAGs are typically present in the photoresist compositions in an amount of from 0.1 to 10 wt % and preferably from 0.1 to 5 wt %, based on total solids.

The photoresist composition further includes a solvent. The solvent may be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), aa polar aprotic solvent (such as dimethyl sulfoxide, dimethyl formamide, and the like), or a combination thereof. The solvent can be present in the photoresist compositions in an amount of from 40 to 99 wt %, preferably from 40 to 70 wt %, based on the total weight photoresist composition.

The photoresist composition may further include one or more optional additives. For example, optional additives may include actinic and contrast dyes, anti-striation agents, plasticizers, speed enhancers, sensitizers, photo-destroyable bases, basic quenchers, surfactants, and the like, or combinations thereof. If present, the optional additives are typically present in the photoresist compositions in an amount of from 0.1 to 10 wt % based on total solids.

Exemplary photo-destroyable bases include, for example, photo-decomposable cations, and preferably those also useful for preparing acid generator compounds, paired with an anion of a weak (pKa>2) acid such as, for example, a C₁₋₂₀ carboxylic acid. Exemplary carboxylic acids include formic acid, acetic acid, propionic acid, tartaric acid, succinic acid, cyclohexylcarboxylic acid, benzoic acid, salicylic acid, and the like.

Exemplary basic quenchers include, for example, linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one and tert-butyl 1,3-dihydroxy-2-(hydroxymethyl)propan-2-ylcarbamate; aromatic amines such as pyridine, and 2,6-di-tert-butyl pyridine; aliphatic amines such as triisopropanolamine, n-tert-butyldiethanolamine, tris(2-acetoxy-ethyl) amine, 2,2′,2″,2′″-(ethane-1,2-diylbis(azanetriyl))tetraethanol, and 2-(dibutylamino)ethanol, 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate and N-(2-acetoxy-ethyl)morpholine; ammonium salts such as quaternary ammonium salts of sulfonates, sulfamates, carboxylates and phosphonates.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an embodiment, the photoresist composition further includes a surfactant polymer including a fluorine-containing repeating unit.

The photoresist compositions as disclosed herein may advantageously be coated in a single application to provide a thick photoresist layer. The thickness of the photoresist layer in a dried state is typically greater than 5 micrometers (μm), for example from 5 to 50 μm or from 5 to 30 μm. As used herein, the “dried state” refers to the photoresist composition comprising 25 wt % or less, for example, 12 wt % or less, 10 wt % or less, 8 wt % or less, or 5 wt % or less of the solvent, based on the total weight of the photoresist composition.

Also provided is a coated substrate formed from the photoresist composition. Such a coated substrate may include: (a) a substrate, and (b) a layer of the photoresist composition disposed over the substrate.

Substrates may be any dimension and shape, and are preferably those useful for photolithography, such as silicon, silicon dioxide, silicon-on-insulator (SOI), strained silicon, gallium arsenide, coated substrates including those coated with silicon nitride, silicon oxynitride, titanium nitride, tantalum nitride, ultrathin gate oxides such as hafnium oxide, metal or metal coated substrates including those coated with titanium, tantalum, copper, aluminum, tungsten, alloys thereof, and combinations thereof. Preferably, the surfaces of substrates herein include critical dimension layers to be patterned including, for example, one or more gate-level layers or other critical dimension layers on the substrates for semiconductor manufacture. Such substrates may preferably include silicon, SOI, strained silicon, and other such substrate materials, formed as circular wafers having dimensions such as, for example, 20 cm, 30 cm, or greater in diameter, or other dimensions useful for wafer fabrication production.

Further provided is a method of forming a pattern that includes applying a layer of the photoresist composition on a substrate; drying the applied photoresist composition to form a photoresist composition layer; exposing the photoresist composition layer to activating radiation; heating the exposed photoresist composition layer; and developing the exposed composition layer to form a resist pattern.

Application of the photoresist may be accomplished by any suitable method, including spin coating, spray coating, dip coating, doctor blading, or the like. For example, applying the layer of photoresist may be accomplished by spin-coating the photoresist in solvent using a coating track, in which the photoresist is dispensed on a spinning wafer. During dispensing, the wafer may be spun at a speed of up to 4,000 rpm, for example, from about 200 to 3,000 rpm, for example, 1,000 to 2,500 rpm. The coated wafer is spun to remove solvent, and soft-baked on a hot plate to remove residual solvent and reduce free volume to densify the film. The soft-bake temperature is typically from 90 to 170° C., for example, from 110 to 150° C. The heating time is typically from 10 seconds to 20 minutes, for example, from 1 minute to 10 minutes, or from 1 minute to 5 minutes. The heating time can be readily determined by one of ordinary skill in the art based on the ingredients of the composition.

The casting solvent can be any suitable solvent known to one of ordinary skill in the art. For example, the casting solvent can be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), a polar aprotic solvent (such as dimethyl sulfoxide, dimethyl formamide, and the like), or a combination thereof. The choice of the casting solvent depends on a particular photoresist composition and can be readily made by one of ordinary skill in the art based on knowledge and experience. The composition may then be dried by using conventional drying methods known to one of ordinary skill in the art.

The photoresist composition may be prepared by dissolving the polymer, the PAG, and any optional components in the appropriate amounts in the casting solvent. The photoresist composition or one or more of the components of the photoresist composition can be optionally subjected to a filtration step and/or ion exchange process using an appropriate ion exchange resin for purification purposes.

Exposure is then carried out using an exposure tool such as a stepper or scanner, in which the film is irradiated through a pattern mask and thereby is exposed pattern-wise. The method may use advanced exposure tools generating activating radiation at wavelengths capable of high-resolution patterning including excimer lasers, such as Krypton Fluoride laser (KrF). It will be appreciated that exposure using the activating radiation decomposes the PAG in the exposed areas and generates acid, and that the acid then effectuates a chemical change in the polymer (deblocking the acid sensitive group to generate a base-soluble group, or alternatively, catalyzing a crosslinking reaction in the exposed areas). The resolution of such exposure tools may be less than 30 nm.

Heating of the exposed composition may take place at a temperature of 100 to 150° C., for example, 110 to 150° C., or 120 to 150° C., or 130 to 150, or 140 to 150° C. The heating time may vary from 30 seconds to 20 minutes, for example, from 1 to about 10 minutes, or from 1 to 5 minutes. The heating time can be readily determined by one of ordinary skill in the art based on the components of the composition.

Developing the exposed photoresist layer is then accomplished by treating the exposed layer with a suitable developer capable of selectively removing the exposed portions of the film (in the case of a positive tone development (PTD) process) or removing the unexposed portions of the film (in the case of a negative tone development (NTD) process). Application of the developer may be accomplished by any suitable method such as described above with respect to application of the photoresist composition, with spin coating being typical. Typical developers for a PTD process include aqueous base developers, for example, quaternary ammonium hydroxide solutions such as tetramethylammonium hydroxide (TMAH), typically 0.26N TMAH, tetraethylammonium hydroxide, tetrabutyl ammonium hydroxide, sodium hydroxide, potassium hydroxide, sodium carbonate, potassium carbonate, and the like. Typical developers for an NTD process include an organic solvent-based developer, chosen for example, from one or more of an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate (nBA), propylene glycol monomethyl ether acetate (PGMEA), ethyl lactate (EL), hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), a polar aprotic solvent (such as dimethyl sulfoxide, dimethyl formamide, and the like), or a combination thereof. In an embodiment, the solvent developer may be a miscible mixture of solvents, for example, a mixture of an alcohol (iso-propanol) and ketone (acetone). For an NTD process, the developer is typically nBA or 2-heptanone. The choice of the developer solvent depends on a particular photoresist composition and can be readily made by one of ordinary skill in the art based on knowledge and experience.

The photoresist may, when used in one or more such pattern-forming processes, be used to fabricate semiconductor devices such as memory devices, processor chips (CPUs), graphics chips, optoelectronic chips, and other such devices.

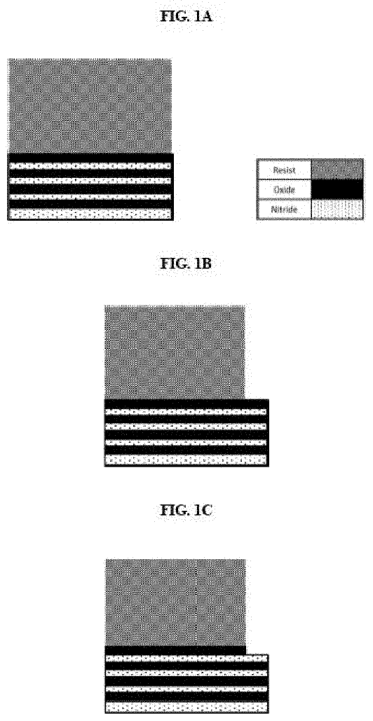

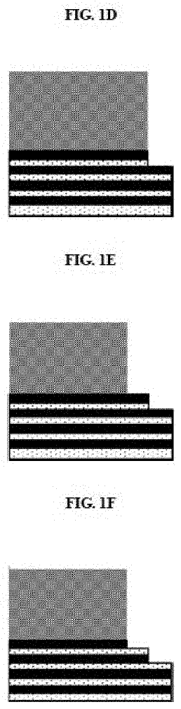

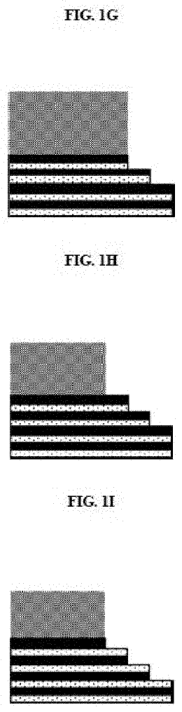

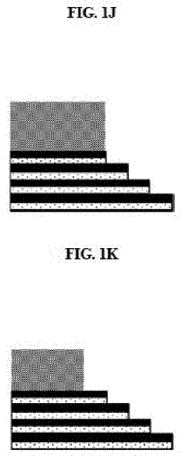

FIGS. 1A to 1K illustrate a method of forming a staircase pattern in accordance with an embodiment (Hong Xiao “3D IC Devices, Technologies, and Manufacturing” SPIE Press, Bellingham Wash. USA).

FIG. 1A shows a structure having a multilayer deposition of alternated silicon oxide (“Oxide”) and silicon nitride (“Nitride”) layers on a silicon surface with a photoresist (“Resist”) layer coated on the wafer surface as an etch mask. The oxide and nitride layers can be formed by various techniques known in the art, for example, chemical vapor deposition (CVD) such as plasma-enhanced CVD (PECVD) or low-pressure CVD (LPCVD). The photoresist layer can be formed as described above. Typically, the photoresist layer is formed by a spin-coating process. The photoresist layer is next patterned by exposure through a patterned photomask and developed as described above, with the resulting structure shown in FIG. 1B. After that, a sequential series of well-controlled oxide and nitride etch and resist trim steps are performed as follows. FIG. 1C shows the structure after the first silicon oxide etch, and FIG. 1D shows the structure after the first silicon nitride etch. After the first pair of oxide and nitride are etched away, a controlled photoresist trim step is performed (FIG. 1E). The trimmed photoresist is then used to etch the first and the second series of oxide and nitride, as shown in FIGS. 1F-G. The photoresist is then trimmed again (FIG. 1H) and the first, second and third pair of oxide/nitride are etched (FIGS. 1I-J). The controlled photoresist trimming is then performed again (FIG. 1K). Suitable oxide and nitride etch and resist trim processes and chemistries are known in the art, with dry-etching processes being typical.

The number of times the photoresist layer can be trimmed may be limited, for example, by its original thickness and etch selectivity. After the minimum thickness limit is reached, the remaining resist is typically stripped, and another photoresist layer formed in its place. The new photoresist layer is patterned, the oxide and nitride layers etched, and resist layer trimmed as described above with respect to the original photoresist layer, to continue formation of the staircase pattern. This process can be repeated multiple times until the desired staircase pattern is completed, typically, when the pattern reaches a desired surface of the substrate, typically the silicon surface of the substrate.

Hereinafter, the present invention is illustrated in more detail with reference to examples. However, these examples are exemplary, and the present invention is not limited thereto.

### EXAMPLES

### Preparation of Resist Polymers

Poly[p-hydroxystyrene-tert-butyl acrylate] (A1), poly[p-hydroxystyrene-1-ethylcyclopentyl acrylate] (A2), poly[p-hydroxystyrene] (A3), and poly[p-hydroxystyrene-tert-butyl acrylate-hexahydro-4,7-methanoindan-5-ol acrylate] (B1) were synthesized by free radical polymerization using the method described in U.S. Patent Publication No. 002/0156199.

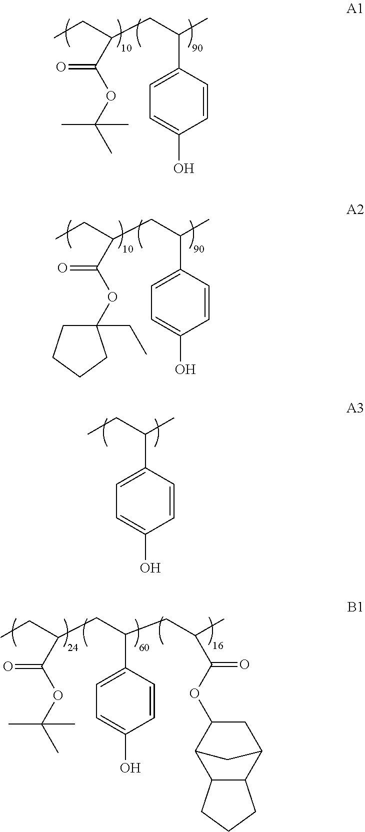

### Example 1 (P1)

The following is a general procedure used to prepare the examples and comparative examples. A reaction flask was charged with a solution of 200 g of copolymer A1 in 2 L of propylene glycol monomethyl ether acetate (PGMEA). Reduced pressure was applied to the reaction flask to concentrate the solution and achieve a water content of less than 200 ppm by weight. The solution was then purged with nitrogen for 40 minutes. To the solution of copolymer A1 was added 41.3 g of isopropyl vinyl ether followed by 0.65 g of trifluoroacetic acid (TFA, 20% solution in PGMEA) in a dropwise manner. The mixture was then stirred at room temperature (about 23° C.) for 19 hours. The resulting product solution was filtered through a column of basic alumina and then filtered through an in-line PTFE membrane filter (0.2 μm pore size, available as ACRO 50). The filtered solution was concentrated under reduced pressure to produce a 50% wt solution of poly(p-(1-isopropoxyethoxy)styrene-p-hydroxystyrene-tert-butyl acrylate) in PGMEA. The copolymer P1 had a M_{w} of 22,300 g/mol, a M. of 13,900 g/mol, and a PDI of 1.6. Molecular weight was determined by GPC using polystyrene standards. The reaction for the synthesis of P1 is shown in Scheme 2.

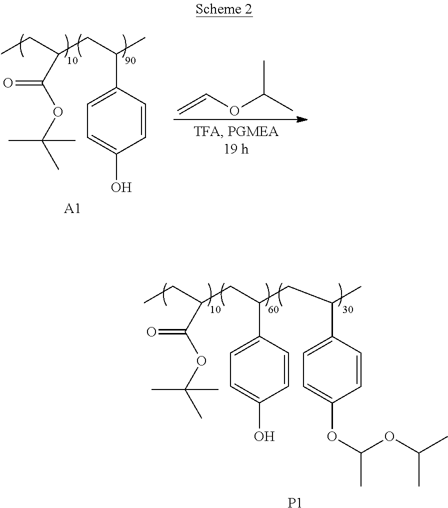

### Example 2 (P2)

The same procedure from Example 1 was followed, except copolymer A2 was used instead of copolymer A1 to produce a 50% wt solution of poly(p-(1-isopropoxyethoxy)styrene-p-hydroxystyrene-1-ethylcyclopentyl acrylate) in PGMEA. The copolymer P2 had a M_{w} of 21,400 g/mol, a M. of 12,600 g/mol, and a PDI of 1.7 as determined by GPC. The reaction for the synthesis of P2 is shown in Scheme 3.

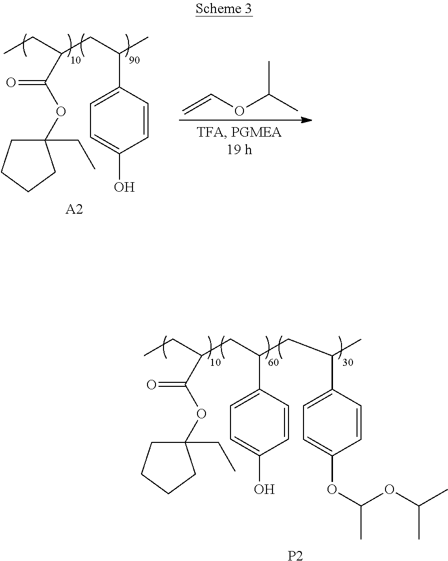

### Comparative Example 1 (C1)

The same general procedure from Example 1 was followed, except ethyl vinyl ether was used instead of isopropyl vinyl ether to produce a 50% wt solution of poly(p-(1-ethoxyethoxy)styrene-p-hydroxystyrene-tert-butyl acrylate) in PGMEA. The copolymer C1 had a M_{w} of 24,100 g/mol, a Mₙ of 15,100 g/mol, and a PDI of 1.6 as determined by GPC. The reaction for the synthesis of C1 is shown in Scheme 4.

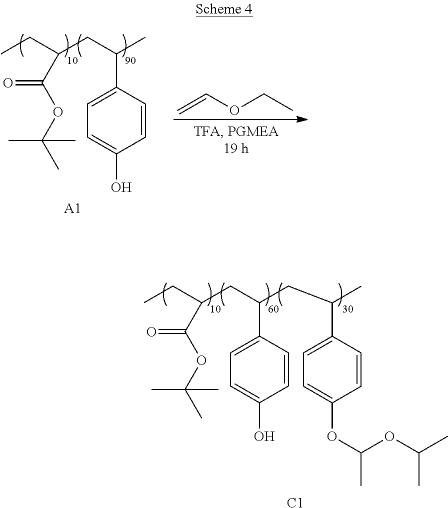

### Comparative Example 2 (C2)

The same general procedure from Example 1 was followed, except N-butyl vinyl ether was used instead of isopropyl vinyl ether to produce a 50% wt solution of poly(p-(1-butoxyethoxy)styrene-p-hydroxystyrene-tert-butyl acrylate) in PGMEA. The copolymer C2 had a M_{w} of 22,700 g/mol, a Mₙ of 14,200 g/mol, and a PDI of 1.6 as determined by GPC. The reaction for the synthesis of C2 is shown in Scheme 5.

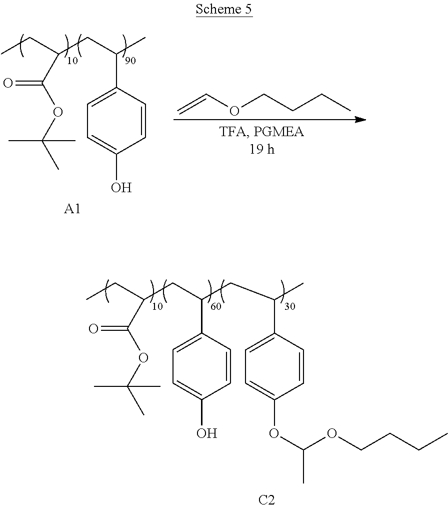

### Comparative Example 3 (C3)

The same general procedure from Example 1 was followed, except cyclohexyl vinyl ether was used instead of isopropyl vinyl ether to produce a 50% wt solution of poly[p-(1-cyclohexyloxyethoxy) styrene-p-hydroxystyrene-tert-butyl acrylate) in PGMEA. The copolymer C3 had a M_{w} of 22,700 g/mol, a Mₙ of 15,100 g/mol, and a PDI of 1.5 as determined by GPC. The reaction for the synthesis of C3 is shown in Scheme 6.

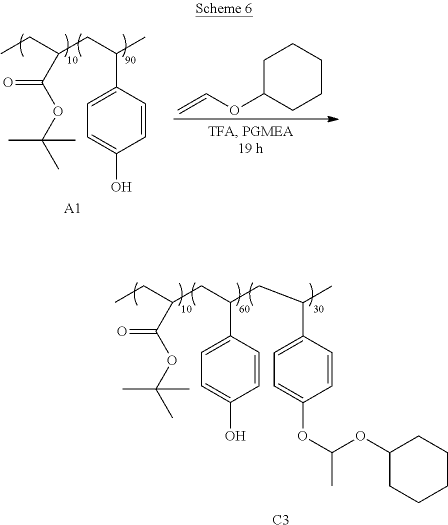

### Comparative Example 4 (C4)

The same general procedure from Example 1 was followed, except tert-butyl vinyl ether was used instead of isopropyl vinyl ether to produce a 50% wt solution of poly(p-(1-tert-butoxyethoxy) styrene-p-hydroxystyrene-tert-butyl acrylate) in PGMEA. The copolymer C4 had a M_{w} of 23,000 g/mol, a Mₙ of 14,400 g/mol, and a PDI of 1.6 as determined by GPC. The reaction for the synthesis of C4 is shown in Scheme 7.

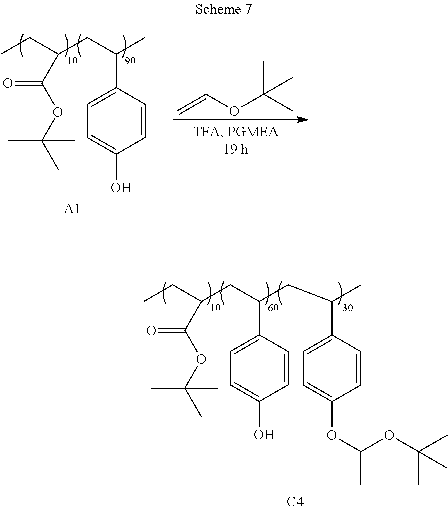

### Comparative Example 5 (C5)

The same general procedure from Example 1 was followed, except polymer A3 was used instead of A1 and ethyl vinyl ether was used instead of isopropyl vinyl ether to produce a 50% wt solution of poly(p-(1-ethoxyethoxy)styrene-p-hydroxystyrene) in PGMEA. The copolymer C5 had a M_{w} of 23,700 g/mol, a Mₙ of 13,900 g/mol, and a PDI of 1.7 as determined by GPC. The reaction for the synthesis of C5 is shown in Scheme 8.

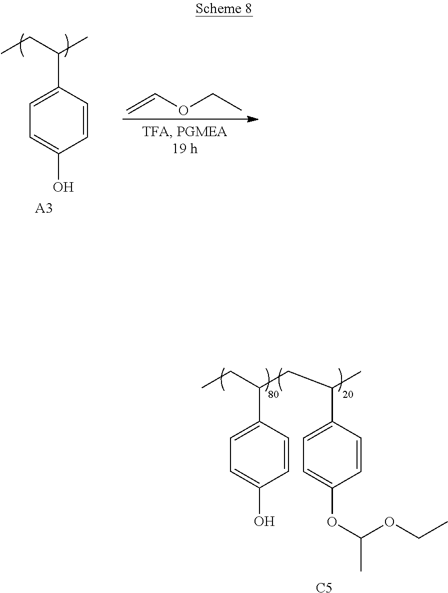

### Comparative Example 6 (C6)

The same general procedure from Example 1 was followed, except polymer A3 was used instead of A1 to produce a 50% wt solution of poly(p-(1-isopropoxyethoxy)styrene-p-hydroxystyrene) in PGMEA. The copolymer C6 had a M_{w} of 22,500 g/mol, a Mₙ of 13,200 g/mol, and a PDI of 1.7 as determined by GPC. The reaction for the synthesis of C6 is the same as shown below in Scheme 8 for Comparative Example 7, except the molar ratio of repeating units is 80:20.

### Comparative Example 7 (C7)

The same general procedure from Example 1 was followed, except polymer A3 was used instead of A1 to produce a 50% wt solution of poly(p-(1-isopropoxyethoxy)styrene-p-hydroxystyrene) in PGMEA. The copolymer C7 had a M_{w} of 24,000 g/mol, a Mₙ of 14,100 g/mol, and a PDI of 1.7 as determined by GPC. The reaction for the synthesis of C7 is shown in Scheme 9.

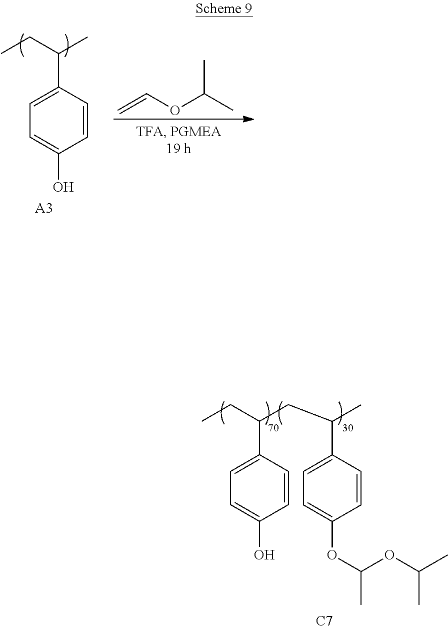

### Resist Compositions

The resist compositions (R1-R3) and comparative resist compositions (CR1-CR10) prepared from the copolymers of Examples 1-2 and Comparative Examples 1-7 are shown in Table 1. In Table 1, the numbers in parentheses indicate the amount of each component in wt % based on a total weight of 100 wt %.

TABLE 1

| Composition | Polymer 1 | Polymer 2 | PAG | Quencher | Additives | Surfactant | Solvents |
|---|---|---|---|---|---|---|---|
| R1 | P1 | — | G1 | Q1 | A1/A2 | L1 | S1/S2/S3 |
| | [35.698] | | [1.1628] | [0.01665] | [3.6/4.5] | [0.0225] | [44/8.25/2.75] |
| R2 | P1 | — | G1 | Q1 | A1/A2 | L1 | S1/S2/S3 |
| | [35.698] | | [1.1628] | [0.01665] | [3.6/4.5] | [0.022] | [44/8.25/2.75] |
| R3 | P2 | — | G1 | Q1 | A1/A2 | L1 | S1/S2/S3 |
| | [35.698] | | [1.1628] | [0.01665] | [3.6/4.5] | [0.022] | [44/8.25/2.75] |
| R4 | P1 | B1 | G1 | Q1 | A1/A2 | L1 | S1/S2/S3 |
| | [17.849] | [17.849] | [1.1628] | [0.01665] | [3.6/4.5] | [0.022] | [44/8.25/2.75] |
| CR1 | C1 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR2 | C2 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR3 | C3 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR4 | C4 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR5 | C5 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR6 | C6 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR7 | C7 | — | G1 | Q1 | A1/A2 | L1 | S1/S2/S3 |
| | [35.698] | | [1.1628] | [0.01665] | [3.6/4.5] | [0.022] | [44/8.25/2.75] |
| CR8 | C1 | B1 | G1 | Q1 | A1/A2 | L1 | S1/S2/S3 |
| | [17.849] | [17.849] | [1.1628] | [0.01665] | [3.6/4.5] | [0.022] | [44/8.25/2.75] |
| CR9 | C2 | B1 | G1 | Q1 | A1/A2 | L1 | S1/S2/S3 |
| | [17.849] | [17.849] | [1.1628] | [0.01665] | [3.6/4.5] | [0.022] | [44/8.25/2.75] |
| CR10 | — | B1 | G1 | Q1 | A1/A2 | L1 | S1/S2/S3 |
| | | [35.698] | [1.1628] | [0.01665 | [3.6/4.5] | [0.022] | [44/8.25/2.75] |

In Table 1, the following abbreviations are used. Q1 is N—N-diethyldodecanamide; A1 is MARUKA LYNCUR N PADG (Maruzen Photochemical Co. Ltd.); A2 is MARUKA LYNCUR NORES (Maruzen Photochemical Co. Ltd.); L1 is POLYFOX PF-656 surfactant (Omnova Solutions, Inc.); S1 is PGMEA; S2 is propylene glycol methyl ether; and S3 is gamma-butyrolactone.

The photoacid generator G1 is prepared as shown in Scheme 10.

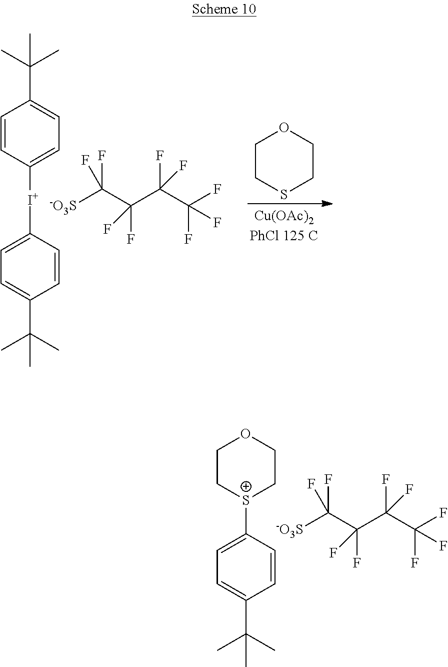

In a 1 L round bottom flask, equipped with a reflux condenser and stirring bar, bis(4-(tert-butyl) phenyl)iodonium perfluorobutane sulfonate (149 g, 216 mmol), and 1,4-oxathiane (25 g, 240 mmol) were dispersed in 400 mL of chlorobenzene. Copper (II) acetate (2.18 g, 12 mmol) was added to the reaction mixture. The reaction was heated at 125° C. for 6 h. The reaction was then cooled to room temperature, diluted with dichloromethane (500 mL), and washed with deionized water (3×200 mL). The organic layer was concentrated to approximatively 100 mL under reduced pressure. Precipitation using methyl tert-butyl ether (MTBE) afforded 105 g of product (81.5%) as a crystalline white solid.

### Lithographic Evaluation

KrF lithographic evaluations were carried out on 200 mm silicon wafers using a TEL Mark 8 track. Initially, silicon wafers were primed with HMDS (at 180° C./60 sec). HMDS-primed wafers were then spin-coated with the aforementioned photoresist compositions in Table 1 and baked at 150° C. for 70 sec to yield a film having a thickness of about 15 micrometers. The photoresist-coated wafers were then exposed using an ASML 300 KrF stepper with a binary mask using 0.52NA. The exposed wafers were post-exposure baked at 110° C. for 50 seconds, and then developed using a 0.26 N tetramethylammonium hydroxide solution (CD-26) for 45 seconds. Metrology was carried out on a Hitachi CG4000 CD-SEM. Table 2 details the residues, photo-speed, etch voids, and surface roughness properties observed for the photoresist compositions.

TABLE 2

| Resist | | | Etch | Surface |
|---|---|---|---|---|
| Composition | Residues | Photospeed | voids | roughness |
| R1 | B | A | A | A |
| R2 | A | A | A | A |
| R3 | B | A | A | A |
| R4 | A | A | A | A |
| CR1 | C | B | B | B |
| CR2 | C | B | B | A |
| CR3 | A | A | C | C |
| CR4 | A | A | C | C |
| CR5 | C | C | C | C |
| CR6 | C | C | C | B |
| CR7 | C | C | B | B |
| CR8 | C | B | B | C |
| CR9 | B | B | B | C |
| CR10 | A | B | C | C |

The properties in Table 2 are scored using the following qualitative terms: A is the best performance; B is acceptable performance; and C is poor performance. As shown in Table 2, the resist compositions including the copolymers of Examples 1 and 2 display unexpectedly faster photospeed, reduced etch voids, and improved surface roughness compared to the photoresist compositions having copolymers that do not incorporate a secondary vinyl ether protected hydroxystyrene.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A polymer comprising:
a first repeating unit comprising a tertiary ester acid labile group; and
a second repeating unit of Formula (1): 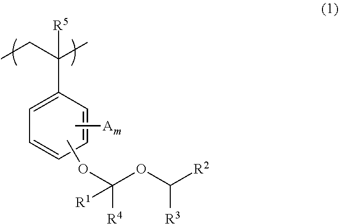
wherein
R¹ is hydrogen, a substituted or unsubstituted C₁₋₁₂ alkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ haloalkyl,
R² and R³ are each independently a straight chain or branched C₁₋₂₀ alkyl, a straight chain or branched C₁₋₂₀ haloalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, a C₇₋₂₀ aryloxyalkyl, or a monocyclic or polycyclic C₄₋₂₀ heteroaryl, each of which is substituted or unsubstituted, provided that R² and R³ together do not form a ring,
R⁴ is a substituted or unsubstituted C₁₋₁₂ alkyl, a substituted or unsubstituted C₇₋₁₈ arylalkyl, a substituted or unsubstituted C₄₋₁₈ heteroarylalkyl, or a substituted or unsubstituted C₁₋₁₂ haloalkyl,
R⁵ is hydrogen, fluorine, a substituted or unsubstituted C₁₋₅ alkyl, or a substituted or unsubstituted C₁₋₅ fluoroalkyl,
each A is independently a halogen, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted, and
m is an integer of 0 to 4.

2. The polymer of claim 1, wherein the second repeating unit is of Formula (1a): 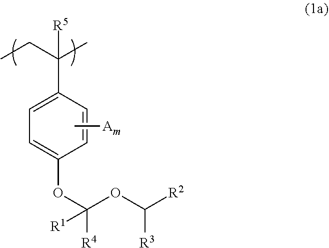
wherein
R¹ is hydrogen, a substituted or unsubstituted C₁₋₁₂ alkyl, a substituted or unsubstituted C₆₋₁₄ aryl, a substituted or unsubstituted C₇₋₁₈ arylalkyl, or a substituted or unsubstituted C₁₋₁₂ haloalkyl,
R² and R³ are each independently a straight chain or branched C₁₋₂₀ alkyl, a straight chain or branched C₁₋₂₀ haloalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, C₇₋₂₀ aryloxyalkyl, or a monocyclic or polycyclic C₄₋₂₀ heteroaryl, each of which is substituted or unsubstituted, provided that R² and R³ together do not form a ring,
R⁴ is a substituted or unsubstituted C₁₋₁₂ alkyl, a substituted or unsubstituted C₇₋₁₈ arylalkyl, a substituted or unsubstituted C₄₋₁₈ heteroarylalkyl, or a substituted or unsubstituted C₁₋₁₂ haloalkyl,
R⁵ is hydrogen, fluorine, a substituted or unsubstituted C₁₋₅ alkyl, or a substituted or unsubstituted C₁₋₅ fluoroalkyl,
each A is independently a halogen, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted, and
m is an integer of 0 to 4.

3. The polymer of claim 1, wherein the second repeating unit is of formula (1b): 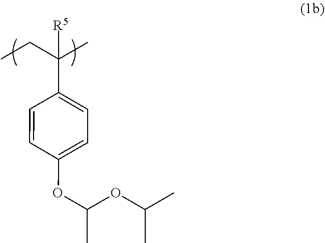
wherein R⁵ is hydrogen, fluorine, a substituted or unsubstituted C₁₋₅ alkyl, or a substituted or unsubstituted C₁₋₅ fluoroalkyl.

4. The polymer of claim 1, wherein the first repeating unit comprising the tertiary ester acid labile group is derived from a monomer of Formula (2a) of Formula (2b): 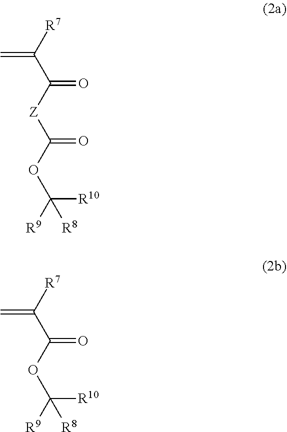
wherein
Z is a linking unit comprising at least one carbon atom and at least one heteroatom,
R⁷ is hydrogen, fluorine, a substituted or unsubstituted C₁₋₅ alkyl, or a substituted or unsubstituted C₁₋₅ fluoroalkyl, and
R⁸, R⁹, and R¹⁰ are each independently a straight chain or branched C₁₋₂₀ alkyl, a monocyclic or polycyclic C₃₋₂₀ cycloalkyl, a monocyclic or polycyclic C₃₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₄₋₂₀ heteroaryl, each of which is substituted or unsubstituted, and any two of R⁸, R⁹, and R¹⁰ together optionally form a ring.

5. The polymer of claim 1, further comprising a third repeat unit derived from a monomer of Formula (3): 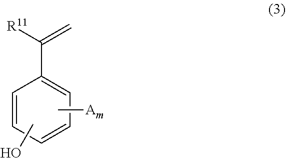
wherein
R¹¹ is hydrogen, fluorine, a substituted or unsubstituted C₁₋₅ alkyl, or a substituted or unsubstituted C₁₋₅ fluoroalkyl, and
A and m are the same as in claim 1.

6. The polymer of claim 5, comprising:
1 to 30 mole percent of the first repeating unit;
1 to 60 mole percent of the second repeating unit; and
30 to 90 mole percent of the third repeating unit,
each based on the total number of moles of repeating units in the polymer.

7. A photoresist composition, comprising:
the polymer of claim 1;
a photoacid generator; and
a solvent.

8. The photoresist composition of claim 7, further comprising a surfactant polymer comprising a fluorine-containing repeating unit.

9. A method of forming a pattern, the method comprising:
applying a layer of the photoresist composition of claim 7 on a substrate;
drying the applied photoresist composition to form a photoresist composition layer;
exposing the photoresist composition layer to activating radiation;
heating the exposed photoresist composition layer; and
developing the exposed composition layer to form a resist pattern.

10. The method of claim 9, wherein the layer of the photoresist composition layer has a thickness of at least 5 micrometers.

11. The method of claim 9 or 10, further comprising forming a staircase pattern in the substrate using the photoresist composition layer as an etch mask, wherein the staircase pattern comprises a plurality of stairs.
